(19) United States
(12) Patent Application Publication
(10) Pub. No.: US 2009/0200631 A1
(43) Pub. Date: Aug. 13, 2009

(54) BACKSIDE ILLUMINATED IMAGING SENSOR WITH LIGHT ATTENUATING LAYER

(75) Inventors: Hsin-Chih Tai, Cupertino, CA (US); Howard E. Rhodes, San Martin, CA (US); Duli Mao, Sunnyvale, CA (US); Vincent Venezia, Sunnyvale, CA (US); Yin Qian, Milpitas, CA (US)

Correspondence Address: BLAKELY SOKOLOFF TAYLOR & ZAFMAN LLP, 1279 Oakmead Parkway, Sunnyvale, CA, 94085-4040, US

(73) Assignee: OMNIVISION TECHNOLOGIES, INC., Sunnyvale, CA (US)

(21) Appl. No.: 12/028,733

(22) Filed: Feb. 8, 2008

(51) Int. Cl. H01L 31/0216

(52) U.S. Cl. 257/435; 257/E31.122

(57) ABSTRACT

A backside illuminated imaging sensor includes a semiconductor substrate, a metal interconnect layer and a light attenuating layer. The semiconductor substrate has a front surface, a back surface, and includes at least one imaging pixel formed on the front surface of the semiconductor substrate. The metal interconnect layer is electrically coupled to the imaging pixel and the light attenuating layer is coupled between the metal interconnect layer and the front surface of the semiconductor substrate. In operation, the imaging pixel receives light from the back surface of the semiconductor substrate, where a portion of the received light propagates through the imaging pixel to the light attenuating layer. The light attenuating layer is configured to substantially attenuate the portion of light received from the imaging pixel.

### TECHNICAL FIELD

This disclosure relates generally to backside illuminated image sensors, and in particular but not exclusively, relates to backside illuminated image sensors having a light attenuating layer.

### BACKGROUND INFORMATION

Many semiconductor imaging sensors today are front side illuminated. That is, they include imaging arrays that are fabricated on the front side of a semiconductor wafer, where light is received at the imaging array from the same front side. However, front side illuminated imaging sensors have many drawbacks, one of which is a limited fill factor.

Backside illuminated imaging sensors are an alternative to front side illuminated imaging sensors that address the fill factor problems associated with front side illumination. Backside illuminated imaging sensors include imaging arrays that are fabricated on the front surface of the semiconductor wafer, but receive light through a back surface of the wafer. Color filters and micro-lenses may be included on the back surface of the wafer in order to improve the sensitivity of the backside illuminated sensor. However, to detect light from the backside, the wafer must be extremely thin. The thickness of the wafer may also be reduced in order to improve the sensitivity. However, higher sensitivity typically results in higher optical crosstalk. That is, as the semiconductor wafer is thinned, light can more easily pass through the wafer and light intended for one pixel may be reflected within the image sensor to other pixels that were not intended to receive the light. Thus, a need exists for a backside illuminated device with improved sensitivity that reduces optical crosstalk.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified.

FIG. 1 is a block diagram illustrating a backside illuminated imaging sensor, in accordance with an embodiment of the invention.

FIG. 2 is a cross-sectional view of a backside illuminated imaging sensor.

FIG. 3 is a cross-sectional view of a backside illuminated imaging sensor, in accordance with an embodiment of the invention.

FIG. 4 is a cross-sectional view of a backside illuminated imaging sensor, in accordance with an embodiment of the invention.

FIG. 5 is a circuit diagram illustrating pixel circuitry of two 4 T pixels within a backside illuminated imaging sensor, in accordance with an embodiment of the invention.

### DETAILED DESCRIPTION

Embodiments of a backside illuminated imaging sensor with light attenuating layer are described herein. In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

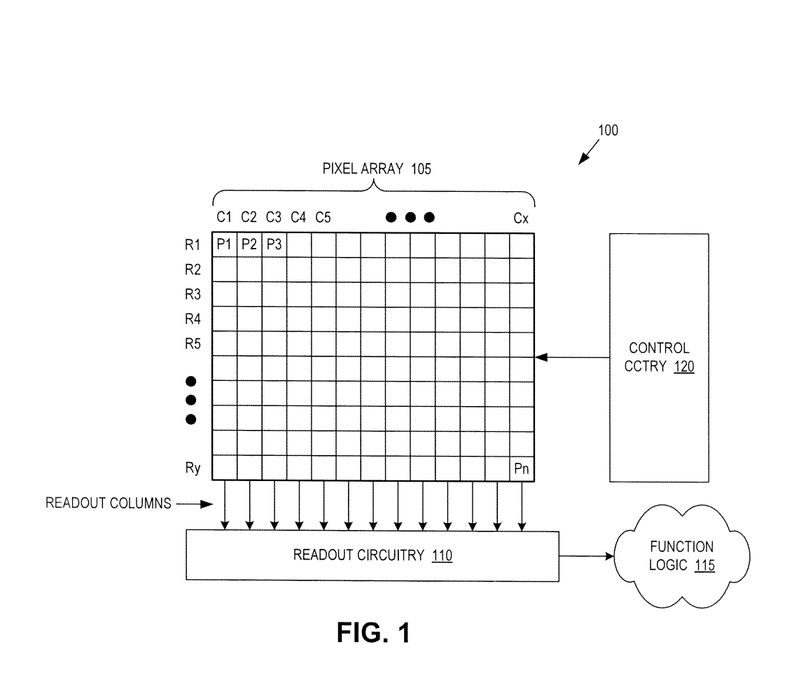

FIG. 1 is a block diagram illustrating a backside illuminated imaging sensor 100, in accordance with an embodiment of the invention. The illustrated embodiment of imaging sensor 100 includes a pixel array 105, readout circuitry 110, function logic 115, and control circuitry 120.

Pixel array 105 is a two-dimensional (“2D”) array of backside illuminating imaging sensors or pixels (e.g., pixels P1, P2 . . . , Pn). In one embodiment, active pixel sensor (“APS”), such as a complementary metal-oxide-semiconductor (“CMOS”) imaging pixel. As illustrated, each pixel is arranged into a row (e.g., rows R1 to Ry) and a column (e.g., column C1 to Cx) to acquire image data of a person, place, or object, which can then be used to render a 2D image of the person, place, or object.

After each pixel has acquired its image data or image charge, the image data is readout by readout circuitry 110 and transferred to function logic 115. Readout circuitry 110 may include amplification circuitry, analog-to-digital conversion circuitry, or otherwise. Function logic 115 may simply store the image data or even manipulate the image data by applying post image effects (e.g., crop, rotate, remove red eye, adjust brightness, adjust contrast, or otherwise). In one embodiment, readout circuitry 110 may readout a row of image data at a time along readout column lines (illustrated) or may readout the image data using a variety of other techniques (not illustrated), such as a serial readout or a full parallel readout of all pixels simultaneously.

Control circuitry 120 is coupled to pixel array 105 to control operational characteristic of pixel array 105. For example, control circuitry 120 may generate a shutter signal for controlling image acquisition.

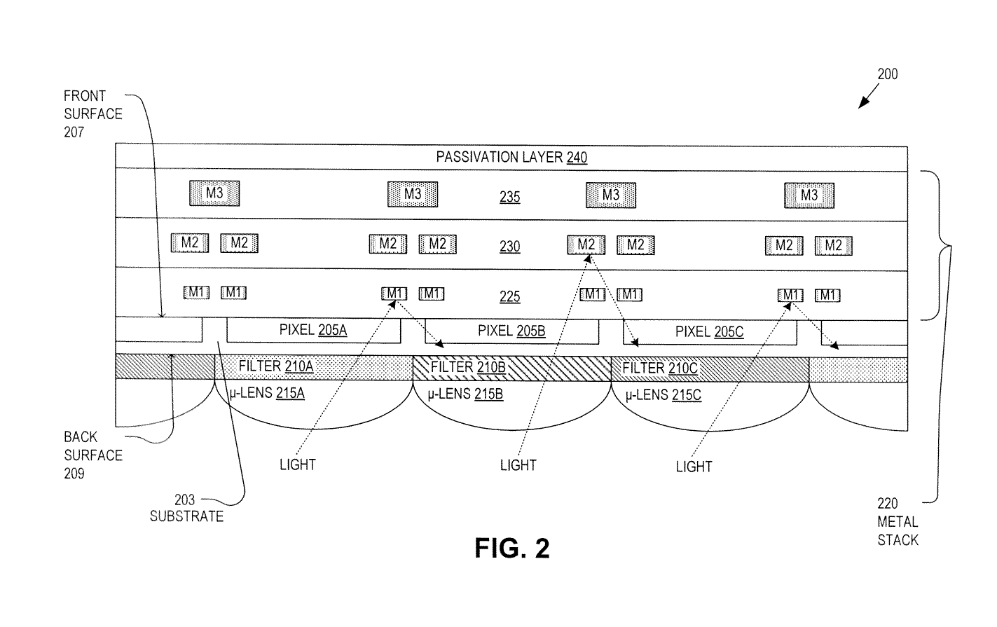

FIG. 2 is a cross-sectional view of a backside illuminated imaging sensor 200. The illustrated embodiment of imaging sensor 200 includes a semiconductor substrate 203, imaging pixels 205, color filters 210, micro-lenses 215, a metal stack 220, and a passivation layer 240. Metal stack 220 is illustrated as including metal interconnect layers M1, M2, and M3 and intermetal dielectric layers 225, 230, and 235.

In the illustrated embodiment of FIG. 2, pixels 205 are formed on a front surface 207 of semiconductor substrate 203 and are configured to receive light from back surface 209. Coupled to back surface 209 are optional color filters 210 to implement a color sensor and micro-lenses 215 to focus light onto pixels 205. As shown in FIG. 2, imaging sensor 200 includes metal stack 220. The illustrated embodiment of metal stack 220 includes three metal layers M1, M2 and M3 separated by intermetal dielectric layers 225, 230, and 235, respectively. Although FIG. 2 illustrates a three layer metal stack, metal stack 220 may include more or less layers for routing signals above front surface 207 of substrate 202. In one embodiment metal interconnect layers M1, M2 and M3 are a metal such as tungsten, aluminum, copper, aluminum-copper alloy, or other alloys. In one embodiment, metal interconnect layers M1, M2 and M3 formed by way of sputtering, collimated sputtering, low pressure sputtering, reactive sputtering, electroplating, chemical vapor deposition, or evaporation. In one embodiment, a passivation layer 240 is disposed over metal stack 220.

During operation, incident light is received at micro-lens 215, which focuses the light through color filter 210 to back surface 209 and through substrate 203 to be received by pixels 205. Pixels 205 then generate one or more electrical signals in response to the received light where these electrical signals are routed through one or more of the metal layers of metal stack 220. However, as seen in FIG. 2, a portion of the light received at pixels 205 may continue propagating through front surface 207 of substrate 203. In some instances this light continues into one or more of the intermetal dielectric layers (e.g., 225 and 230) and is reflected by the metal layers (e.g., M1, M2, M3) back towards a different (e.g., adjacent) pixel, where this pixel now generates a new electrical signal in response to the reflected light. Light reflecting back to an adjacent or different pixel in this manner is referred to herein as “optical crosstalk” and increases noise and reduces the quality in the resulting image produced by imaging sensor 200.

In one example, pixel 205A is configured to receive substantially only light in the red frequency range by way of color filter 210A being a red color filter. Pixel 205B may be similarly configured to received substantially only light in the green frequency range by way of color filter 210B being a green color filter. In this example, light is received at micro-lens 215A, filters into red light by color filter 210A and then propagates through substrate 203 to pixel 205A, where pixel 205A generates an electrical signal representative of the red light received at pixel 205A. A portion of the red light then continues propagating through front surface 207 and is reflected off of metal interconnect layer M1 back towards pixel 205B. Instead of pixel 205B generating electrical signals only in response to green light received from its color filter 210B, pixel 205B now generates electrical signals from both the green light and from the red light reflected from adjacent pixel 205A. Thus, the resulting image produced by imaging sensor 200 may have inaccurate color values generated as a result of this optical crosstalk. That is, pixel 205B may output a higher value as a result of the combined green and reflected red light. Additional optical crosstalk may result from light being reflected off of one or more of the metal interconnect layers, such as M2 and M3.

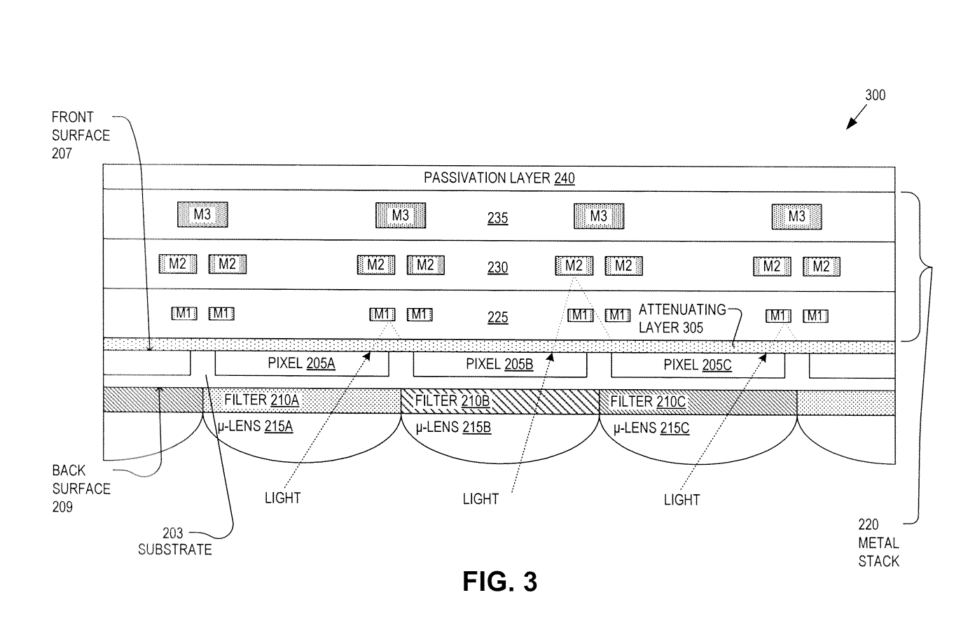

FIG. 3 is a cross-sectional view of a backside illuminated imaging sensor 300, in accordance with an embodiment of the invention. Imaging sensor 300 is one possible implementation of at least a portion of imaging sensor 100 shown in FIG. 1. The illustrated embodiment of imaging sensor 300 includes substrate 203, imaging pixels 205, color filters 210, micro-lenses 215, metal stack 220, passivation layer 240, and light attenuating layer 305.

As shown in FIG. 3, imaging sensor 300 includes a light attenuating layer 305 disposed between metal stack 220 and front surface 207 of semiconductor substrate 203. Light attenuating layer 305 is configured to attenuate light that continues propagating through pixels 205 to the light attenuating layer 305 in order to reduce the effects of optical crosstalk. In one embodiment, light attenuating layer 305 is directly coupled to the front surface 207 of semiconductor substrate 203. In one embodiment, light attenuating layer 305 is directly coupled to at least one metal interconnect layer (e.g., M1, M2, and M3) of metal stack 220.

In one embodiment, light attenuating layer 305 is configured to attenuate light by a minimum threshold amount. For example, light attenuating layer 305 may be configured to attenuate light by at least 30 percent. The minimum threshold amount of light attenuated by light attenuating layer 305 may be configured by adjustment of a variety of aspects of the attenuating layer 305. For example, the thickness of attenuating layer 305 may be adjusted to increase or decrease light attenuation. In one example, the amount of attenuation may be increased by increasing the thickness of light attenuating layer 305. In another example, the amount of attenuation may be adjusted by careful selection of the material(s) used for light attenuating layer 305. In one embodiment, light attenuating layer 305 includes carbon. In one embodiment, light attenuating layer 305 is a layer of silicon carbide.

In operation of imaging sensor 300, incident light is received at micro-lens 215, which focuses the light through color filter 210 to back surface 209 and through substrate 203 to be received by pixels 205. Pixels 205 then generate one or more electrical signals in response to the received light where these electrical signals are routed through one or more of the metal layers of metal stack 220. As with the previous example, a portion of the light received at pixels 205 may continue propagating through front surface 207 of substrate 203. However, with the inclusion of light attenuating layer 305, a substantial amount of the light is attenuated as the light passes through light attenuating layer 305.

An additional benefit of light attenuating layer 305 is that light may be attenuated multiple times as it passes through light attenuating layer 305 in different directions. For example, after the light is first attenuated by passing through light attenuating layer 305 in a first direction, the remaining light may be reflected by metal layers back towards a different pixel. However, the reflected light must again pass through light attenuating layer 305 and will be further attenuated, thereby reducing the optical crosstalk discussed above.

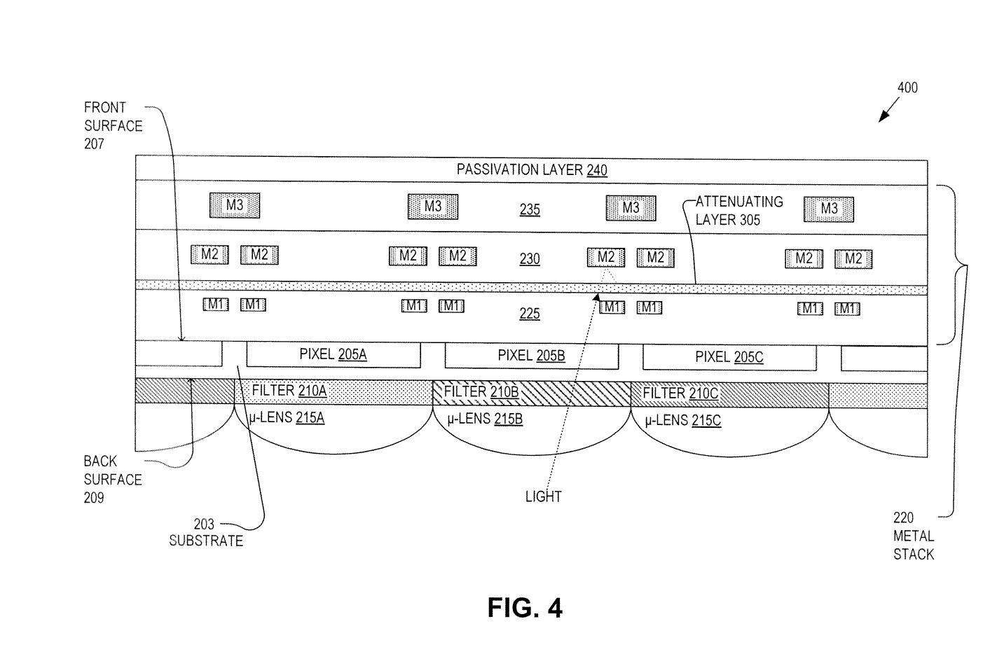

FIG. 4 is a cross-sectional view of a backside illuminated imaging sensor, in accordance with an embodiment of the invention. Imaging sensor 400 is one possible implementation of at least a portion of imaging sensor 100 shown in FIG. 1. The illustrated embodiment of imaging sensor 400 includes substrate 203, imaging pixels 205, color filters 210, micro-lenses 215, metal stack 220, passivation layer 240, and light attenuating layer 305.

Imaging sensor 400 is similar to the embodiments of imaging sensor 300, but now the light attenuating layer 305 is disposed between two of the metal interconnect layers (e.g., M1 and M2). The embodiment of FIG. 4 may be used when it is not desired or convenient to have a layer between metal stack 220 and front surface 207 of semiconductor substrate 203. Although FIG. 4 illustrates light attenuating layer 305 as between the M1 and M2 metal interconnect layers, light attenuating layer 305 may alternately be placed between the M2 and M3 layers, or any other metal interconnect layers to reduce the reflection of light back to pixels 205.

In one embodiment, imaging sensor 400 may include a plurality of light attenuating layers 305. For example, a light attenuating layer 305 may be disposed between the M1 and M2 layers and another light attenuating layer 305 may be disposed between the M2 and M3 layers. Additionally, the embodiments of FIG. 3 and FIG. 4 may be combined such that there is a light attenuating layer disposed between the front surface 207 of semiconductor substrate 203 and metal stack 220 and another light attenuating layer disposed between metal interconnect layers of the metal stack 220. The inclusion of more that one light attenuating layer may provide the benefit of additional reduction in reflected light and thus, a further reduction in optical crosstalk.

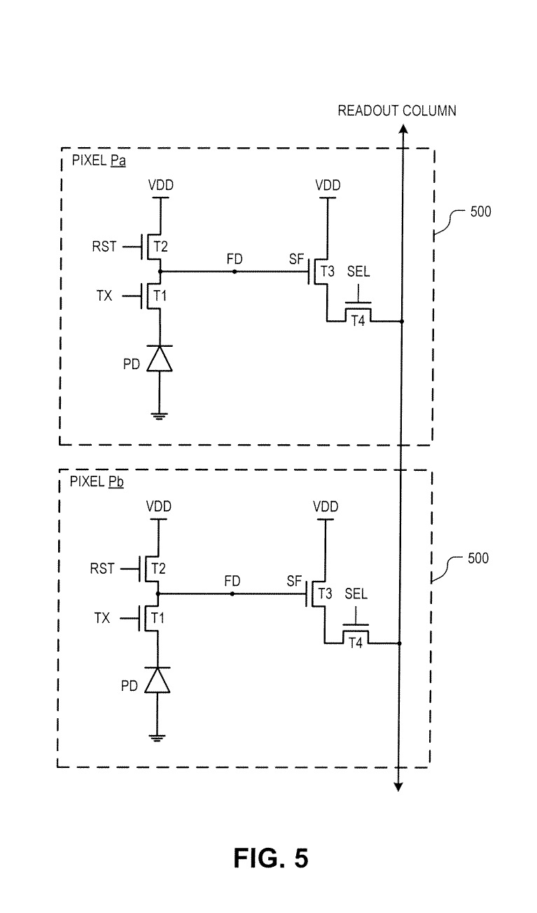

FIG. 5 is a circuit diagram illustrating pixel circuitry 500 of two four-transistor (“4 T”) pixels within a backside illuminated imaging array, in accordance with an embodiment of the invention. Pixel circuitry 500 is one possible pixel circuitry architecture for implementing each pixel within pixel array 100 of FIG. 1 or pixel 205 of FIGS. 2-4. However, it should be appreciated that embodiments of the present invention are not limited to 4 T pixel architectures; rather, one of ordinary skill in the art having the benefit of the instant disclosure will understand that the present teachings are also applicable to 3 T designs, 5 T designs, and various other pixel architectures.

In FIG. 5, pixels Pa and Pb are arranged in two rows and one column. The illustrated embodiment of each pixel circuitry 500 includes a photodiode PD, a transfer transistor T1, a reset transistor T2, a source-follower (“SF”) transistor T3, and a select transistor T4. During operation, transfer transistor T1 receives a transfer signal TX, which transfers the charge accumulated in photodiode PD to a floating diffusion node FD.

Reset transistor T2 is coupled between a power rail VDD and the floating diffusion node FD to reset (e.g., discharge or charge the FD to a preset voltage) under control of a reset signal RST. The floating diffusion node FD is coupled to the gate of SF transistor T3. SF transistor T3 is coupled between the power rail VDD and select transistor T4. SF transistor T3 operates as a source-follower providing a high impedance output from floating diffusion node FD. Finally, select transistor T4 selectively couples the output of pixel circuitry 500 to the readout column line under control of a select signal SEL. In one embodiment, the TX signal, the RST signal, and the SEL signal are generated by control circuitry 120. The TX signal, the RST signal, the SEL signal, VDD, and ground may be routed in pixel circuitry 500 by way of metal interconnect layers M1, M2, and M3. In one embodiment, transistors T1, T2, T3, and T4, photodiode PD and floating diffusion node FD may be connected as shown in FIG. 5 by way of metal interconnect layers M1, M2, and M3.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. A backside illuminated imaging sensor, comprising:
a semiconductor substrate having a front surface and a back surface, the semiconductor substrate having at least one imaging pixel formed on the front surface of the semiconductor substrate;
a metal interconnect layer electrically coupled to the imaging pixel; and
a light attenuating layer coupled between the metal interconnect layer and the front surface of the semiconductor substrate, wherein the imaging pixel receives light from the back surface of the semiconductor substrate, where a portion of the received light propagates through the imaging pixel to the light attenuating layer, wherein the light attenuating layer is configured to substantially attenuate the portion of light received from the imaging pixel.

2. The imaging sensor of claim 1, wherein the light attenuating layer is directly coupled to the front surface of the semiconductor substrate.

3. The imaging sensor of claim 2, wherein the light attenuating layer is further directly coupled to the metal interconnect layer.

4. The imaging sensor of claim 1, wherein the metal interconnect layer is one of a plurality of metal interconnect layers.

5. The imaging sensor of claim 4, wherein at least one of the plurality of metal interconnect layers is disposed between the light attenuating layer and the front surface of the semiconductor substrate.

6. The imaging sensor of claim 1, wherein the light attenuating layer comprises carbon.

7. The imaging sensor of claim 6, wherein the light attenuating layer is a layer of silicon carbide.

8. The imaging sensor of claim 1, wherein the light attenuating layer is configured to attenuate the portion of light that propagates through the imaging pixel to the light attenuating layer by a minimum threshold amount.

9. The imaging sensor of claim 8, wherein the minimum threshold amount is approximately equal to 30 percent.

10. A method, comprising:
receiving an optical signal at a back surface of a semiconductor substrate;
transmitting the optical signal through the semiconductor substrate to an imaging pixel formed on a front surface of the semiconductor substrate;
generating electrical signals responsive to the optical signal with the imaging pixel, wherein a portion of the optical signal is propagated through the imaging pixel to the front surface of the semiconductor substrate;
routing the electrical signals from the imaging pixel to a metal interconnect layer electrically coupled to the imaging pixel; and
attenuating substantially the portion of the optical signal that is propagated through the imaging pixel with a light attenuating layer coupled between the metal interconnect layer and the front surface of the semiconductor substrate.

11. The method of claim 10, wherein attenuating substantially the portion of the optical signal that is propagated through the imaging pixel with the attenuating layer comprises attenuating a first portion of the optical signal as the optical signal propagates through the attenuating layer in a first direction and attenuating a second portion of the optical signal as the optical signal is reflected back through the attenuating layer in a second direction.

12. The method of claim 10, wherein attenuating the portion of the optical signal that is propagated through the imaging pixel comprises attenuating the optical signal by at least 30 percent with the light attenuating layer.

13. The method of claim 10, wherein the light attenuating layer comprises carbon.

14. The method of claim 13, wherein the light attenuating layer is a layer of silicon carbide.

15. An imaging sensor comprising:
a semiconductor substrate having a front surface and a back surface, the semiconductor substrate having a backside illuminated array of imaging pixels, wherein each imaging pixel includes:
a metal interconnect layer; and
a light attenuating layer coupled between the metal interconnect layer and the front surface of the semiconductor substrate, wherein the imaging pixel receives light from the back surface of the semiconductor substrate, where a portion of the received light propagates through the imaging pixel to the light attenuating layer, wherein the light attenuating layer is configured to substantially attenuate the portion of light received from the imaging pixel.

16. The imaging sensor of claim 15, wherein the light attenuating layer is directly coupled to the front surface of the semiconductor substrate.

17. The imaging sensor of claim 16, wherein the light attenuating layer is further directly coupled to the metal interconnect layer.

18. The imaging sensor of claim 15, wherein the metal interconnect layer is one of a plurality of metal interconnect layers, and wherein at least one of the plurality of metal interconnect layers is disposed between the light attenuating layer and the front surface of the semiconductor substrate.

19. The imaging sensor of claim 15, wherein the light attenuating layer comprises carbon.

20. The imaging sensor of claim 19, wherein the light attenuating layer is a layer of silicon carbide.

21. The imaging sensor of claim 15, wherein the light attenuating layer is configured to attenuate the portion of light that propagates through the imaging pixel to the light attenuating layer by at least 30 percent.
